(19) United States
(12) Patent Application Publication
(10) Pub. No.: US 2010/0015322 A1
(43) Pub. Date: Jan. 21, 2010

(54) Method And Apparatus For Coating A Film On A Substrate

(75) Inventor: Chih-Hao Huang, Taipei Hsien (TW)

Correspondence Address: WPAT, PC;INTELLECTUAL PROPERTY ATTORNEYS, 2030 MAIN STREET, SUITE 1300, IRVINE, CA, 92614, US

(73) Assignee: CHENG UEI PRECISION INDUSTRY CO., LTD., Taipei Hsien (TW)

(21) Appl. No.: 12/176,006

(22) Filed: Jul. 18, 2008

(51) Int. Cl. C23C 16/52; B05C 11/00

(52) U.S. Cl. 427/8; 118/712

(57) ABSTRACT

A method and an apparatus for coating a film on a substrate are presented. According to principle of the invention, firstly, a control device controls a first coating device to spray a coating solution onto the substrate. Then, a sensor monitors viscosity data of the coating solution presented between the first coating device and the substrate during movement of the first coating device and sends the viscosity data to the control device, or the sensor monitors viscosity data of the coating solution coated on the substrate and sends the viscosity data to the control device. Lastly, the control device controls a second coating device to spray a coating solution onto the substrate after the first coating device according to signals about the viscosity data from the control device.

### BACKGROUND OF THE INVENTION

1. Field of the Invention

The present invention generally relates to a method and an apparatus for coating a film on a substrate, and more particularly to a method and an apparatus capable of coating a flat film on a substrate.

2. The Related Art

Coating a substrate with a coating solution for forming a film thereon has already become an indispensable technology in every field. A conventional method for coating the film on the substrate is described as follows: firstly, spray the coating solution onto the substrate with a constant flow amount, and then, a film of uniform thickness is formed on the substrate after the coating solution is dried. However, in an actual craft, surfaces of the substrate often show a plurality of pits and protrusions thereon. Because the flow amount of the coating solution keeps invariable at the pits, the protrusions and other parts of the substrate, after the substrate is coated with the coating solution, the flatness of the film thus formed will be degraded. Therefore, a method and an apparatus capable of coating an extremely flat film on the substrate are required.

### SUMMARY OF THE INVENTION

An object of the present invention is to provide a method and an apparatus for coating an extremely flat film on a substrate.

The method is described hereinafter. Firstly, control a first coating device to spray a coating solution onto the substrate. Then, monitor viscosity data of the coating solution presented between the first coating device and the substrate during movement of the first coating device and send the viscosity data to a control device, or monitor viscosity data of the coating solution coated on the substrate and send the viscosity data to the control device. Lastly, control a second coating device to spray a coating solution onto the substrate after the first coating device according to signals about the viscosity data from the control device.

The apparatus includes a first coating device adapted for spraying a coating solution onto the substrate, a second coating device adapted for spraying a coating solution onto the substrate after the first coating device, a sensor adapted for monitoring viscosity data of the coating solution presented between the first coating device and the substrate during movement of the first coating device along the substrate or coated on the substrate, and a control device adapted for receiving the viscosity data from the sensor and sending signals about the viscosity data to control the second coating device to spray.

As described above, the method and the apparatus can coat a flat film on the substrate using the control device which controls the second coating device to adjust a flow amount of the coating solution according to the signals about the viscosity data from the control device.

### BRIEF DESCRIPTION OF THE DRAWINGS

The present invention will be apparent to those skilled in the art by reading the following description of a preferred embodiment thereof, with reference to the accompanying drawings, in which:

FIG. 1 is a lateral view of an apparatus for coating a film on a substrate in accordance with an embodiment of the present invention, wherein a flat part of the substrate is covered by the apparatus;

FIG. 2 is a lateral view of the apparatus of FIG. 1, wherein a pit of the substrate is covered by a first coating device of the apparatus; and

FIG. 3 is a lateral view of the apparatus of FIG. 1, wherein the pit of the substrate is covered by a second coating device of the apparatus.

### DETAILED DESCRIPTION OF THE PREFERRED EMBODIMENT

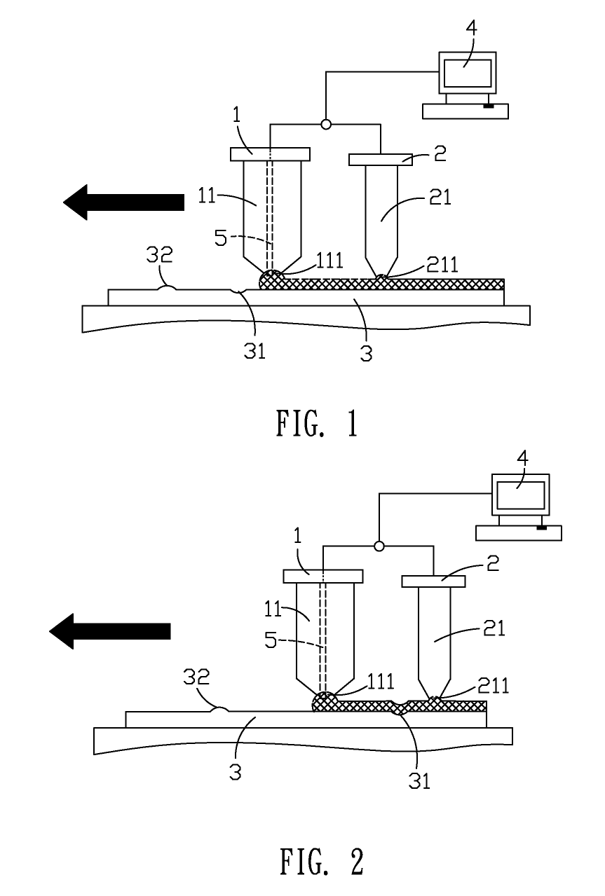

Referring to FIG. 1, an apparatus for coating a film on a substrate in accordance with an embodiment of the present invention includes a first coating device 1, a second coating device 2, a control device 4 and a sensor 5.

The first coating device 1 is nail-shaped and defines a first receiving room 11 for receiving a coating solution therein and a first sprue 111 at bottom thereof communicating with the first receiving room 11 for making the coating solution flow out. The second coating device 2 is similar to the first coating device 1 and defines a second receiving room 21 and a second sprue 211. The sensor 5 is cudgel-shaped and is vertically disposed in the first receiving room 11. A top end of the sensor 5 is fixed in the first coating device 1 and a bottom end thereof stretches out of the first sprue 111 slightly. The control device 4 controls the first coating device 1, the second coating device 2 and the sensor 5. When a substrate 3 is to be coated, the first coating device 1 and the second coating device 2 are located on the substrate 3. The control device 4 controls the first coating device 1 to move forward and spray the coating solution contained in the first receiving room 11 onto the substrate 3 continuously in a uniform flow rate along the entire surface of the substrate 3. The control device 4 also controls the second coating device 2 to move forward in such a manner that the second coating device 2 is constantly distanced from the first coating device 1 and then spray the coating solution contained in the second receiving room 21 onto the substrate 3 continuously along the substrate 3 after the first coating device 1. During coating process of the substrate 3, the sensor 5 monitors viscosity data of the coating solution between the first coating device 1 and the substrate 3 and then sends the monitored viscosity data to the control device 4 in which a set of predefined viscosity data is stored. The control device 4 compares the monitored viscosity data with the predefined viscosity data and based on the comparison, the control device 4 sends signals about the viscosity data to control the second coating device 2 to spray the coating solution.

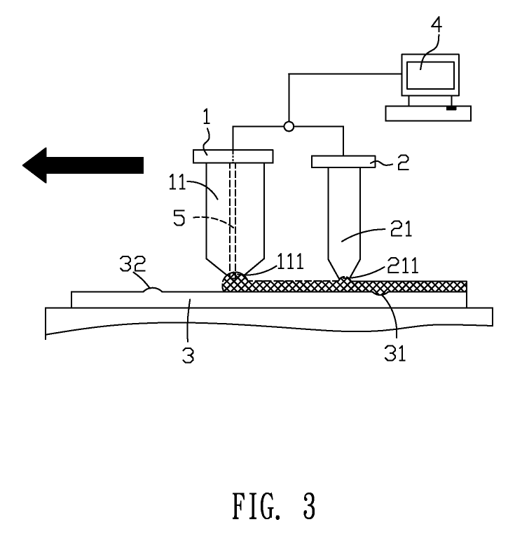

Referring to FIG. 2 and FIG. 3, when a pit 31 of the substrate 3 is coated with the coating solution by the first coating device 1, the monitored viscosity data from the sensor 5 is smaller than the predefined viscosity data stored in the control device 4 because of the distance between the first sprue 111 and the substrate 3 elongating. Therefore, when the second coating device 2 moves to the pit 31, the control device 4 controls the second coating device 2 to increase the flow amount of the coating solution for coating a flat film. On the other hand, when a protrusion 32 of the substrate 3 is coated with the coating solution by the first coating device 1, the monitored viscosity data from the sensor 5 is greater than the predefined viscosity data stored in the control device 4 because of the distance between the first sprue 111 and the substrate 3 shortening. Therefore, when the second coating device 2 moves to the protrusion 32, the control device 4 controls the second coating device 2 to diminish the flow amount of the coating solution for coating the flat film.

Referring to FIGS. 1-3 again, a method for coating a film on a substrate in accordance with the embodiment of the present invention is described hereinafter.

Firstly, the control device 4 controls the first coating device 1 to move forward and spray the coating solution therein onto the substrate 3 continuously in the uniform flow amount along the entire surface of the substrate 3 to be coated.

Then, the sensor 5 monitors the viscosity data of the coating solution between the first coating device 1 and the substrate 3 continuously along with the first coating device 1 moving forward and sends the monitored viscosity data to the control device 4 having the predefined viscosity data stored therein.

Lastly, the control device 4 controls the second coating device 2 to move forward with the constant time difference from the first coating device 1 and spray the coating solution therein onto the substrate 3 continuously along the substrate 3 after the first coating device 1 according to the signals about the viscosity data from the control device 4.

The control device 4 compares the monitored viscosity data with the predefined viscosity data, and if the monitored viscosity data is smaller than the predefined viscosity data, the control device 4 controls the second coating device 2 to increase the flow amount of the coating solution, while in case that the monitored viscosity data is greater than the predefined viscosity data, the control device 4 controls the second coating device 2 to diminish the flow amount of the coating solution.

As described above, the method and the apparatus in accordance with the embodiment of the present invention can coat the flat film on the substrate 3 using the control device 4 which controls the second coating device 2 to adjust the flow amount of the coating solution according to the signals about the viscosity data from the control device 4.

The foregoing description of the present invention has been presented for purposes of illustration and description. It is not intended to be exhaustive or to limit the invention to the precise form disclosed, and obviously many modifications and variations are possible in light of the above teaching. For example, the sensor 5 is disposed in other positions of the apparatus so as to monitor the viscosity data of the coating solution at all places of the substrate 3. Such modifications and variations that may be apparent to those skilled in the art are intended to be included within the scope of this invention as defined by the accompanying claims.

What is claimed is:

1. A method for coating a film on a substrate, comprising:
controlling a first coating device to spray a coating solution onto the substrate;
monitoring viscosity data of the coating solution presented between the first coating device and the substrate during movement of the first coating device and sending the viscosity data to a control device; and
controlling a second coating device to spray a coating solution onto the substrate where the coating solution has been coated by the first coating device according to signals about the viscosity data from the control device.

2. The method as claimed in claim 1, wherein the first coating device and the second coating device move forward with a constant time difference such that they are separated with each other a constant distance.

3. The method as claimed in claim 1, wherein the control device has a predefined viscosity data, the control device compares the monitored viscosity data with the predefined viscosity data, and if the monitored viscosity data is smaller than the predefined viscosity data, then the control device controls the second coating device to increase a flow amount of the coating solution, otherwise if the monitored viscosity data is greater than the predefined viscosity data, the control device controls the second coating device to diminish the flow amount of the coating solution.

4. A method for coating a film on a substrate, comprising:
controlling a first coating device to spray a coating solution onto the substrate;
monitoring viscosity data of the coating solution coated on the substrate and sending the viscosity data to a control device; and
controlling a second coating device to spray a coating solution onto the substrate after the first coating device according to signals about the viscosity data from the control device.

5. An apparatus for coating a film on a substrate, comprising:
a first coating device adapted for spraying a coating solution onto the substrate;
a second coating device adapted for spraying a coating solution onto the substrate after the first coating device;
a sensor adapted for monitoring viscosity data of the coating solution presented between the first coating device and the substrate during movement of the first coating device along the substrate; and
a control device adapted for receiving the viscosity data from the sensor and sending signals about the viscosity data to control the second coating device to spray.

6. The apparatus as claimed in claim 5, wherein the sensor is fixed in the first coating device and an end thereof stretches out of the first coating device for monitoring the viscosity data of the coating solution presented between the first coating device and the substrate.

7. The apparatus as claimed in claim 5, wherein the first coating device and the second coating device move forward with a constant time difference such that they are separated with each other a constant distance.

8. The apparatus as claimed in claim 5, wherein the control device has a predefined viscosity data, the control device is able to compare the monitored viscosity data with the predefined viscosity data, and when the monitored viscosity data is smaller than the predefined viscosity data, the control device controls the second coating device to increase a flow amount of the coating solution, while when the monitored viscosity data is greater than the predefined viscosity data, the control device controls the second coating device to diminish the flow amount of the coating solution.

9. An apparatus for coating a film on a substrate, comprising:
a first coating device adapted for spraying a coating solution onto the substrate;
a second coating device adapted for spraying a coating solution onto the substrate after the first coating device;
a sensor adapted for monitoring viscosity data of the coating solution coated on the substrate; and
a control device adapted for receiving the viscosity data from the sensor and sending signals about the viscosity data to control the second coating device to spray.
